(19) United States
(12) Patent Application Publication
(10) Pub. No.: US 2022/0408549 A1
(43) Pub. Date: Dec. 22, 2022

(54) PACKAGING STRUCTURE FOR CIRCUIT UNITS

(71) Applicant: Weifang Goertek Microelectronics Co., Ltd., Weifang, Shandong (CN)

(72) Inventors: Haisheng Wang, Weifang, Shandong (CN); Dewen Tian, Weifang, Shandong (CN); Qinglin Song, Weifang, Shandong (CN)

(73) Assignee: Weifang Goertek Microelectronics Co., Ltd., Weifang, Shandong (CN)

(21) Appl. No.: 17/620,839

(22) PCT Filed: Dec. 6, 2019
(86) PCT No.: PCT/CN2019/123559

§ 371 Date: Dec. 20, 2021

(30) Foreign Application Priority Data
Jun. 18, 2019 (CN) 201910529561.3

(51) Int. Cl. H05K 1/02

(52) U.S. Cl. CPC H05K 1/0231; H05K 1/0209; H05K 2201/10098; H05K 2201/10151; H05K 2201/10121; H05K 2201/0175

(57) ABSTRACT

Disclosed is a packaging structure for circuit units, comprising: a circuit baseplate, wherein the circuit baseplate is provided thereon with a circuit unit, the circuit unit including a silicon dioxide layer and an electronic device arranged on the silicon dioxide layer; an insulator, wherein the insulator surrounds the circuit unit; and an electromagnetic shielding layer, wherein the electromagnetic shielding layer covers the circuit unit and the insulator.

### CROSS-REFERENCE TO RELATED APPLICATIONS

This application is a National Stage of International Application No. PCT/CN2019/123559, filed on Dec. 6, 2019, which claims priority to Chinese Patent Application No. 201910529561.3, filed on Jun. 18, 2019, both of which are hereby incorporated by reference in their entireties.

### TECHNICAL FIELD

The present disclosure relates to the technical field of electronics, and in particular to a packaging structure for circuit units,

### BACKGROUND

In the prior art, a circuit unit is usually plastic packaged directly by a layer of colloid so as to package the circuit unit of a printed circuit board, thus packaging the circuit unit between the colloid and the printed circuit board. But in this way, the circuit unit has poor heat dissipation performance, and the circuit unit tends to be interfered by an external radio-frequency signal, resulting in poor electromagnetic shielding performance

### SUMMARY

A main purpose of the present disclosure is to provide a packaging structure for a circuit unit, which aims at solving the problems of too high cost and too many manufacturing steps of the packaging structure for a circuit unit.

In order to realize this purpose, the embodiments of the present disclosure provide a packaging structure for a circuit unit. The packaging structure for a circuit unit includes: a circuit baseplate, where the circuit baseplate is provided thereon with the circuit unit, the circuit unit including a silicon dioxide layer and an electronic device arranged on the silicon dioxide layer; air insulator, where the insulator surrounds the circuit unit; and an electromagnetic shielding layer, where the electromagnetic shielding layer covers the circuit unit and the insulator.

Preferably, the insulator is convexly arranged between the circuit units such that the insulator and the silicon dioxide layer form a recess in a surrounding mode, and the electromagnetic shielding layer fills the recess to contact with the silicon dioxide layer.

Preferably, the silicon dioxide layer is arranged on the circuit baseplate through surface mounting.

Preferably, the electromagnetic shielding layer is made of semiconductive silver adhesive, where the semiconductive silver adhesive is obtained by adding metal particles into epoxy resin.

Preferably, the electromagnetic shielding layer is made of aluminium nitride ceramics.

Preferably, the electromagnetic shielding layer is made of organic glass.

Preferably, the electromagnetic shielding layer is provided with a through hole, the circuit unit is a patch antenna, and the patch antenna includes: a radio-frequency circuit, where the radio-frequency circuit is formed on the silicon dioxide layer; a radiating body, where the radiating body is formed on a surface, facing away from the silicon dioxide layer, of the electromagnetic shielding layer; and a feeder, where the feeder penetrates through the through hole and is connected to the radio-frequency circuit and the radiating body.

Preferably, the circuit unit is a photosensitive element, the photosensitive element being formed on the silicon dioxide layer, and the electromagnetic shielding layer being transparent or semitransparent.

Preferably, the electromagnetic shielding layer is provided with at least two through holes, the circuit unit is a pressure sensing circuit, and the pressure sensing circuit includes: a controller, where the controller is formed on the silicon dioxide layer;

a pressure sensor, where the pressure sensor is arranged on a surface, facing away from the silicon dioxide layer, of the electromagnetic shielding layer; and a connecting line, where the connecting line penetrates through the through hole and is connected to the controller and the pressure sensor.

In order to realize the purpose, the embodiments of the present disclosure provide an electronic apparatus including the packaging structure for a circuit unit according to any one of the items.

According to the packaging structure for a circuit unit of the present disclosure, the circuit baseplate, the silicon dioxide layer and the electromagnetic shielding layer are arranged in an overlaid mode, and a silicon layer substrate on the silicon dioxide in the prior art is removed, thus achieving a desirable electromagnetic shielding effect; the electromagnetic shielding layer is made of a high-dielectric-constant material and has efficient electric conduction and heat conduction characteristics, so that heat generated in a working process of the circuit unit may be timely transferred and dissipated, adverse factors of low heat conduction performance, high brittleness and low reliability of the silicon layer substrate are eliminated, and the step that a metal package shell is formed by metal again on the circuit baseplate is omitted, thus facilitating batch production; and the silicon layer substrate is removed, so a thickness of the whole packaging, structure for a circuit unit becomes thinner.

### BRIEF DESCRIPTION OF THE DRAWINGS

In order to illustrate embodiments of the present disclosure or technical solutions in the prior art more clearly, brief introduction on drawings needed to be used in description of the embodiments or the prior art is made below. It is obvious that the drawings described below are merely some embodiments of the present disclosure. Those skilled in the an further can obtain other drawings in accordance with structures shown in the drawings without creative efforts,

FIG. 1 is a schematic diagram of a process of Embodiment 1 of a packaging process for a circuit unit in the present disclosure;

FIGS. 2a to 2f are schematic diagrams of as structure and a process of one embodiment of the packaging process for a circuit unit in the present disclosure;

FIG. 3 is a structural schematic diagram of a packaging structure for a circuit unit in the present disclosure;

FIG. 4 is a schematic diagram of a specific process of S20 in the packaging process for a circuit unit in the present disclosure;

FIG. 5 is a schematic diagram of a specific process of S221 in the packaging process for a circuit unit in the present disclosure; and

FIG. 6 is a schematic diagram of a process of Embodiment 2 of the packaging process for a circuit unit in the present disclosure.

Further description on implementation of purposes, functional characteristics and advantages of the present disclosure is made in combination with embodiments with reference to drawings.

### DESCRIPTION OF THE EMBODIMENTS

Clear and intact description on the technical solution in the embodiments of the present disclosure will be made in combination with drawings in the embodiments of the present disclosure. It is obvious that the embodiments described are only a part of embodiments of the present disclosure, and are not all of embodiments thereof. Based on the embodiments of the present disclosure, all the other embodiments obtained by those of ordinary skill in the art without inventive effort are within the scope of the present disclosure.

It should be noted that all directional indications (such as upper, lower, left, right, front, rear, etc.) in the embodiments of the present disclosure are only used to describe the relative positional relation, the movement situation, etc. among components in a certain posture (as shown in the drawings). If the specific posture changes, the directional indications will change accordingly.

Furthermore, the technical solutions between the various embodiments may be combined with each other, but must be on the basis that the combination thereof can be implemented by those of ordinary Skill in the art. In case of a contradiction with the combination of the technical solutions or a failure to implement the combination, it should be considered that the combination of the technical solutions does not exist, and is not within the protection scope of the present disclosure.

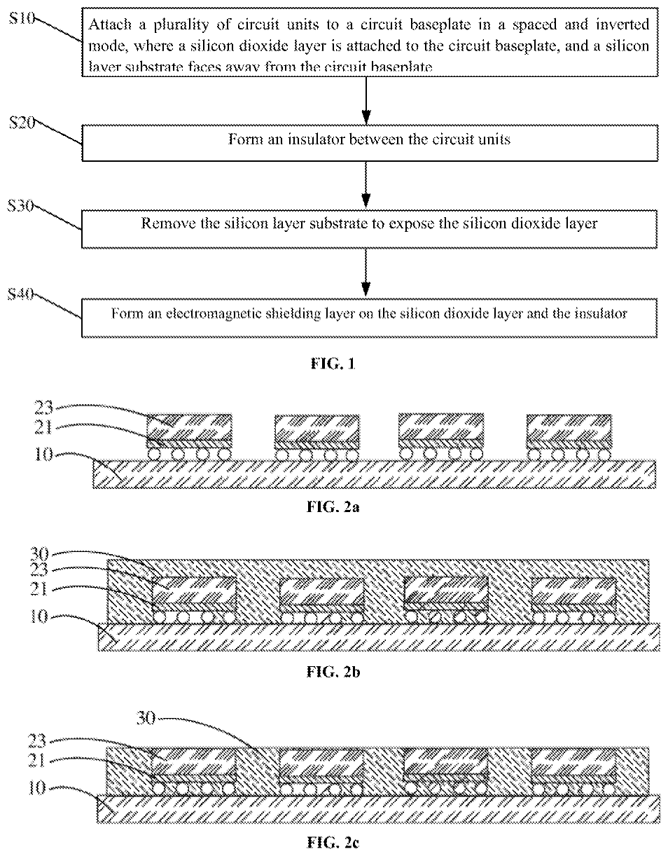

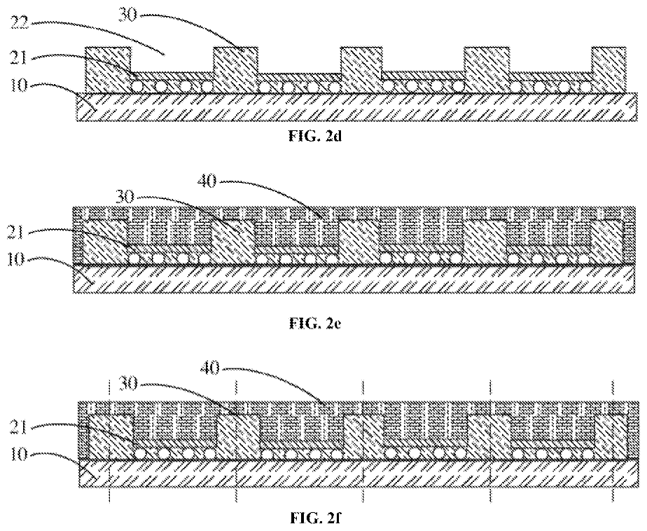

With reference to FIGS. 1 to 3, FIG. 2a is a schematic diagram of attaching a plurality of circuit units 20 to a circuit baseplate in a spaced and inverted mode in a packaging process for a circuit unit; FIG. 2b is a schematic diagram of plastic packaging epoxy resin; FIG. 2c is a schematic diagram of ground epoxy resin; FIG. 2d is a schematic diagram of a corroded silicon layer substrate; FIG. 2e is a schematic diagram of forming an electromagnetic shielding layer; and FIG. 2f is a schematic diagram of cutting the circuit units into circuit modules. The embodiments of the present disclosure provide a packaging process for a circuit unit, which is used for manufacturing the packaging structure for a circuit unit of the present disclosure. The circuit unit includes a silicon layer substrate and a silicon dioxide layer overlaid on the silicon layer substrate. As Embodiment 1 of the packaging process for a circuit unit of the present disclosure, the packaging process for a circuit unit includes:

S10, a plurality of circuit units are attached to a circuit baseplate in a spaced and inverted mode, where the silicon dioxide layer is attached to the circuit baseplate, and the silicon layer substrate faces away from the circuit baseplate.

In the embodiment, the plurality of circuit units are attached to the circuit baseplate, such as a printed circuit board, through a surface mount technology (SMT), a die bond (DB) technology or other mount technologies. In the prior art, the circuit unit is usually attached to the circuit baseplate in a forward mode, that is, the silicon layer substrate of the circuit unit is attached to the circuit baseplate and the silicon dioxide layer is arranged. on the silicon layer substrate. However, in the embodiment, the circuit unit is attached to the circuit baseplate in an inverted mode, that is, the silicon dioxide layer is attached to the circuit baseplate and the silicon layer substrate faces away from the circuit baseplate and arranged on the silicon dioxide layer, which aims to arrange the silicon layer substrate on an upper surface to facilitate subsequent removal of the silicon layer substrate and only leave the silicon dioxide layer.

S20, an insulator is formed between the circuit units.

In the embodiment, the circuit units are arranged in a spaced mode so as to fill a space between the circuit units with the insulator, the insulator may be made of non-conductive epoxy resin, etc., an insulating medium is formed on the circuit baseplate through a coating process or a dispensing process, an insulating, medium on the silicon layer substrate is removed through a grinding process to expose the silicon layer substrate, and an insulating medium between the circuit units is left to form the insulator. The insulator insulates different circuit units and also protects the circuit unit.

S30, the silicon layer substrate is removed to expose the silicon dioxide layer.

In the embodiment, the silicon layer substrate exposed at the upper surface may be removed through an etching process or an acid liquor corrosion process so as to expose the silicon dioxide layer at an outer surface.

S40, an electromagnetic shielding layer is formed on the silicon dioxide layer and the insulator.

In the embodiment, the electromagnetic shielding layer may be formed on the silicon dioxide layer and the insulator through the coating process, the dispensing process or the sputtering process, the electromagnetic shielding layer forms a metal shielding cover to isolate a circuit chip in the electromagnetic shielding layer from an external electromagnetic interference signal, thus achieving high resistance to harmonic interference of the circuit chip.

In conclusion, according to the present disclosure, the circuit units are attached to the circuit baseplate in a spaced and inverted mode, the insulator tills the gap between the circuit units, then the silicon layer substrate of the circuit unit is removed, and the electromagnetic shielding layer is formed on the insulator and the silicon dioxide layer, thus achieving a desirable electromagnetic shielding effect; the electromagnetic shielding layer is made of a high-dielectric-constant .material and has efficient electric conduction and heat conduction characteristics, so that heat generated in a working process of the circuit unit may be timely transferred and dissipated, adverse factors of low heat conduction performance, high brittleness and low reliability of the silicon layer substrate are eliminated, and the step that a metal package shell is formed by .metal again on the circuit baseplate is omitted, thus facilitating batch production.

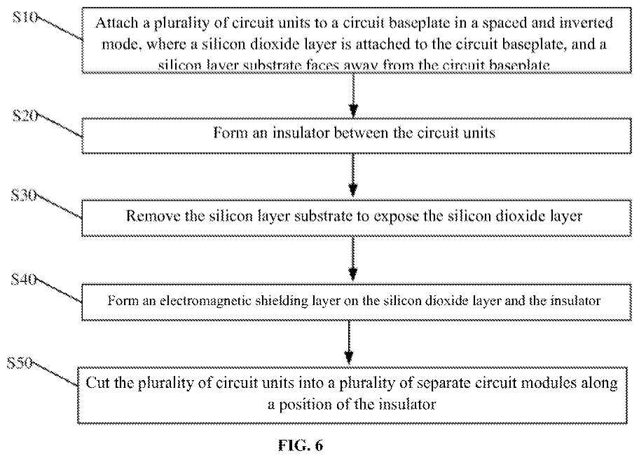

With reference to FIGS. 2 and 4, based on the Embodiment 1 an Embodiment 2 of the packaging process fora circuit unit of the present disclosure is provided. The S20 includes the following steps that

S21, the circuit baseplate is plastic packaged by epoxy resin, where the epoxy resin covers the circuit baseplate and the circuit unit, and the epoxy resin fills a gap between the circuit units; and

S22, the epoxy resin is ground to remove epoxy resin covering the circuit unit and leave epoxy resin between the circuit units, so as to form the insulator,

In the embodiment, the circuit baseplate is plastic packaged by the epoxy resin so as to plastic package the whole circuit baseplate by the epoxy resin, meanwhile the epoxy resin fills the gap between the circuit units, and then the epoxy resin is ground through the grinding process, so that a thickness of the epoxy resin is gradually reduced until the silicon layer substrate of the circuit unit is exposed at a surface, then the epoxy resin filling the space between the circuit units is left to form the insulator, and in this case, the insulator is flush with the silicon layer substrate of the circuit unit

Based on the Embodiments 1 and 2, an Embodiment 3 of the packaging process for a circuit unit of the present disclosure is provided. The S22 includes the following step that

S221, a grinding jig is controlled to rotate in the same direction as the epoxy resin, where the grinding jig and the epoxy resin have different rotation speeds.

In the embodiment, the grinding jig is controlled to rotate in the same direction as the epoxy resin. For example, the grinding jig and the epoxy resin rotate anticlockwise or clockwise, and the grinding jig and the epoxy resin move relatively due to a rotating speed difference between the grinding jig and the epoxy resin. The grinding jig and the epoxy resin rotate in the same direction, so that the circuit unit in the epoxy resin may be prevented from being damaged by stress caused by huge pulling force generated between the grinding jig and the epoxy resin, thus improving a yield of the circuit unit.

With reference to FIG. 5, based on the Embodiments 1 to 3, an Embodiment 4 of the packaging process for a circuit unit of the present disclosure is provided. The S221 includes the following steps that

S2211, the grinding jig is controlled to rotate at a first preset rotating speed to conduct rough grinding on the epoxy resin;

S2212, the grinding jig is controlled to rotate at a second preset rotating speed to conduct line grinding on the epoxy resin; and

S2213, the grinding jig is controlled to polish the epoxy resin,

where the first preset rotating speed is greater than the second preset rotating speed.

In the embodiment, at an initial stage of grinding the epoxy resin, the epoxy resin is thick, so the epoxy resin may be subjected to the rough grinding so as to accelerate grinding, and in this case, the epoxy resin is ground by means of diamond with a high roughness at a surface of the grinding jig. For example, during the rough grinding, a grinding wheel of the grinding jig may be set to have a feeding speed 30 mm/s and a rotating speed 1200-4500 turns/min, the roughness of the diamond on the grinding wheel may be set as 300#, and a rotating speed of the epoxy resin may be set as 2500-4500 turns/min.

At a fine grinding stage, the epoxy resin already becomes thin, so the feeding speed of the grinding wheel of the grinding jig may be appropriately reduced to 3 min/s and/or the roughness of the diamond may be appropriately reduced to 5000#-8000# to prevent the circuit unit in the epoxy resin from being damaged. The rotating speed of the grinding wheel of the grinding jig may be appropriately reduced or remain unchanged but a speed of the epoxy resin is slightly increased so as to reduce a speed difference between the grinding jig, and the epoxy resin, thus achieving a tine grinding effect.

At a polishing stage, a surface of the epoxy resin is ground by means of coated abrasive. A hardness of the coated abrasive is low, so the rotating speed and the feeding speed may be not limited. The coated abrasive makes the surface of the epoxy resin smoother and flatter and removes the epoxy resin remaining on the silicon layer substrate so as to completely expose the silicon layer substrate, thus facilitating subsequent complete removal of the silicon layer substrate.

Based on the Embodiments 1 to 4, an Embodiment 5 of the packaging process tor a circuit unit of the present disclosure is provided, The S30 includes the following step that

S31, the silicon layer substrate is removed through corrosion by hydrofluoric acid solution.

In the embodiment, the silicon layer substrate is etched away by means of the hydrofluoric acid solution. A main component of the silicon layer substrate is Si, and a chemical equation of a reaction between Si and hydrofluoric acid is Si+4HF=SiF4↑ +2H2↑. If a concentration of the hydrofluoric acid is high, generated silicon tetrafluoride may form H2SiF6 an ionic equation is Si+6HF==SiF6(2-)+2H2↑, and SiF4 may constantly volatilize, so that chemical equilibrium is broken. The process is continuously conducted due to volatilization of SiF4, so the silicon layer substrate may be removed by means of the hydrofluoric acid in a low-cost mode.

Preferably, in the S31, the hydrofluoric acid solution includes the hydrofluoric acid and barium sulfate, and a concentration ratio of the hydrofluoric acid to the barium sulfite is 10:1.

in the embodiment, the barium sulfate is used for determining whether Si in the silicon layer substrate is completely dissolved and etched. A concentration of the hydrofluoric acid is 1.2 ml/L, a concentration of the barium sulfate is 0.12 ml/L, and the concentration ratio of the hydrofluoric acid to the barium sulfate is 10:1, so that it is guaranteed that the hydrofluoric acid has a high corrosion speed.

Based on the Embodiments 1 to 5, an Embodiment 6 of the packaging process for a circuit unit of the present disclosure is provided. The S40 includes the following step that

S41, the electromagnetic shielding layer is formed on the silicon dioxide layer through a dispensing process, a coating process or a sputtering process.

In the embodiment, the electromagnetic shielding layer has an electromagnetic shielding function and is made of semiconductive silver adhesive, aluminium nitride ceramics or organic glass, where the semiconductive silver adhesive is obtained by adding metal particles into the epoxy resin. When the circuit unit is a photosensitive element, the semiconductive silver adhesive, the aluminium nitride ceramics and the organic glass are transparent or semitransparent, so that light is capable of entering a conductive shield from the electromagnetic shielding layer to be received by the photosensitive element.

With reference to FIG. 6, based on the Embodiments 1 to 6, an Embodiment 7 of the packaging process for a circuit unit of the present disclosure is provided. After the S40, the process further includes the following step that

S50, the plurality of circuit units are cut into a plurality of separate circuit modules along a position of the insulator.

In the embodiment, the plurality of circuit units are cut into the plurality of separate circuit modules along the position of the insulator, that is, the circuit modules may be mounted in an electronic apparatus for use. According to the present disclosure, electromagnetic shielding is conducted on different circuit units on the same circuit baseplate, and then the different circuit units are cut into the circuit modules capable of being independently used, so that production efficiency is improved, each of the circuit modules has the efficient electric conduction and heat conduction characteristics and desirable electromagnetic shielding performance, the heat generated in a working process of the circuit modules may be timely transferred and dissipated, and the adverse factors of the low heat conduction performance, the high brittleness and the low reliability of the silicon layer substrate are eliminated.

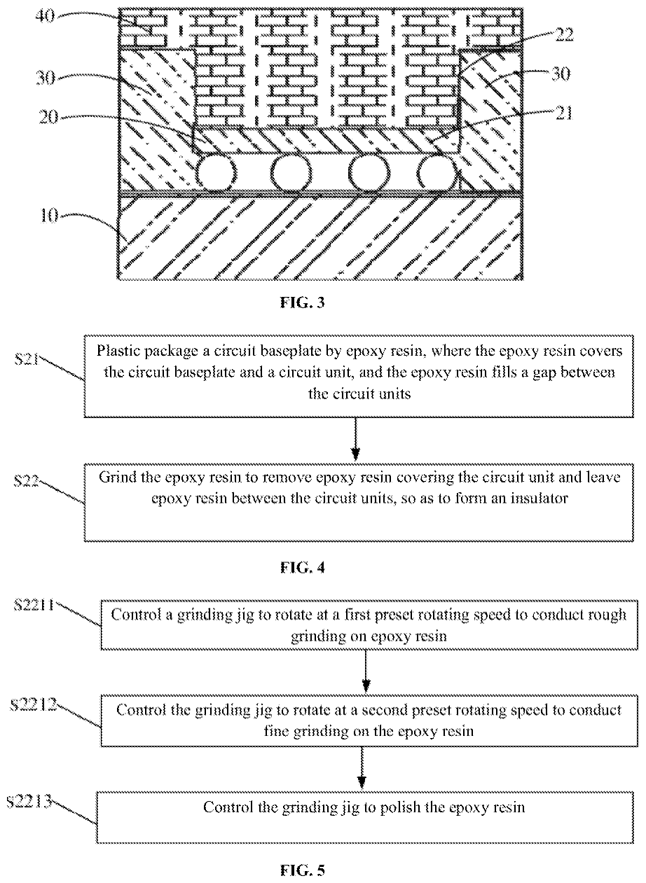

With reference to FIGS. 2-3, in order to realize the purpose, the embodiments of the present disclosure provide a packaging structure 100 for a circuit unit 20, The packaging structure 100 for a circuit unit 20 is manufactured through a packaging process for a circuit unit 20. The packaging structure 100 for a circuit unit 20 includes: a circuit baseplate 10, where the circuit baseplate 10 is provided with the circuit unit 20, and the circuit unit 20 includes a silicon dioxide layer 21 and an electronic device (not shown in the figures) arranged on the silicon dioxide layer 21; an insulator 30, where the insulator 30 surrounds the circuit unit 20; and an electromagnetic shielding layer 40, where the electromagnetic shielding layer 40 covers the circuit unit 20 and the insulator 30.

In the embodiment, the circuit baseplate 10, the silicon dioxide layer 21 and the electromagnetic shielding layer 40 are arranged in an overlaid mode, and a silicon layer substrate 23 on the silicon dioxide layer 21 in the prior art is removed (see FIGS. 2a-2c), thus achieving the desirable electromagnetic shielding effect; the electromagnetic shielding layer 40 is made of the high-dielectric-constant material and has the efficient electric conduction and heat conduction characteristics, so that the heat generated in the working process of the circuit unit 20 may be timely transferred and dissipated, the adverse factors of the low heat conduction performance, the high brittleness and the low reliability of the silicon layer substrate 23 are eliminated, and the step that the metal package shell is formed by the metal again on the circuit baseplate 10 is omitted, thus facilitating the batch production; and the silicon layer substrate 23 is removed, so a thickness of the whole packaging structure 100 for a circuit unit 20 becomes thinner. For example, when the circuit unit 20 is a radio-frequency (RF) unit, a thickness of the packaging structure 100 for a circuit unit 20 may be made to be 400 mm.

Preferably the insulator 30 is convexly arranged between the circuit units 20 such that the insulator and the silicon dioxide layer 21 form a recess 22 in a surrounding mode, and the electromagnetic shielding layer 40 fills the recess 22 to contact with the Silicon dioxide layer 21.

In the embodiment, the recess 22 is formed by corroding an original silicon layer substrate 23 of the circuit unit 20 by hydrofluoric acid, and the silicon layer substrate 23 is flush with the insulator 30 through the grinding process before being corroded; and the recess 22 may be filled with the electromagnetic shielding layer 40, so that the electromagnetic shielding layer 40 makes direct contact with the silicon dioxide layer 21, heat generated by the circuit unit 20 is timely transferred out, the electromagnetic shielding layer 40 is limited in the recess 22 and connected to the silicon dioxide layer 21 at the insulator 30, and connecting stability of the electromagnetic shielding layer 40 may be enhanced.

Preferably, the silicon dioxide layer 21 is arranged on the circuit baseplate 10 through surface mounting. In the embodiment, the plurality of circuit units 20 are attached to the circuit baseplate 10, such as a printed circuit board, through a SMT, a DB technology or other mount technologies, the circuit unit 20 is attached to the circuit baseplate 10 in an inverted mode, that is, the silicon dioxide layer 21 is attached to the circuit baseplate 10 and the silicon layer substrate 23 faces away from the circuit baseplate 10 and arranged on the silicon dioxide layer 21, which aims to arrange the silicon layer substrate 23 on an upper surface to facilitate subsequent removal of the silicon layer substrate 23 and leave the silicon dioxide layer 21 to be connected to a magnetic shielding layer.

Preferably, the electromagnetic shielding layer 40 is made of semiconductive silver adhesive and the semiconductive silver adhesive is obtained by adding metal particles into epoxy resin, or the electromagnetic shielding layer 40 is made of aluminium nitride ceramics, or the electromagnetic shielding layer 40 is made of organic glass; and when the circuit unit 20 is a photosensitive element, the semiconductive silver adhesive, the aluminium nitride ceramics and the organic glass are transparent or semitransparent, so that light is capable of entering a conductive shield from the electromagnetic shielding layer 40 to be received by the photosensitive dement.

In an embodiment, the electromagnetic shielding layer 40 is provided with a through tot shown in the figure), the circuit unit 20 is a patch antenna (not shown in the figure), and the patch antenna includes: a radio-frequency circuit (not shown in the figure), where the radio-frequency circuit is formed on the silicon dioxide layer a radiating body (not shown in. the figure), where the radiating body is formed on a surface, facing away from the silicon dioxide layer 21, of the electromagnetic shielding layer 40; and a feeder (not shown in the figure), where the feeder penetrates through the through hole and is connected to the radio-frequency circuit and the radiating body.

In the embodiment, the electromagnetic shielding layer 40 is provided with the through hole, and the feeder penetrates through the through hole to be connected to the radio-frequency circuit and the radiating body, so that a radio-frequency signal of the radio-frequency circuit is transmitted to the radiating body via the feeder, and the radiating body radiates the radio-frequency signal. Due to existence of the electromagnetic shielding layer 40, the radio-frequency signal of the radio-frequency circuit may be shielded in the electromagnetic shielding layer 40, the radio-frequency circuit cannot generate electromagnetic interference to a surrounding circuit, and the electromagnetic shielding layer 40 makes direct contact with the radio-frequency circuit, so that heat generated in a working process of the radio-frequency circuit may be transferred out. Moreover, the patch antenna does not have the silicon layer substrate 23, so a thickness of the patch antenna may be made to be very low, such as 400 mm, thus facilitating thinness and flattening of an electronic product.

Preferably, the electromagnetic shielding layer 40 is provided with at least two through holes (not shown in the figure), the circuit unit 20 is a pressure sensing, circuit, and the pressure sensing circuit includes: a controller (not shown in the figure), where the controller is formed on the silicon dioxide layer 21;

a pressure sensor (not shown in the figure), where the pressure sensor is arranged on a surface, facing away from the silicon dioxide layer 21, of the electromagnetic shielding layer 40; and a connecting line (not shown in the figure), where the connecting line penetrates through the through hole and is connected to the controller and the pressure sensor.

In the embodiment, the electromagnetic shielding layer 40 is provided with the through hole, and the connecting line penetrates through the through hole and is connected. to the controller and the pressure sensor, so that a pressure signal detected by the pressure. sensor is transmitted to the controller via the connecting line, and the controller conducts subsequent processing on the pressure signal. Due to the existence of the electromagnetic shielding layer 40 an external electromagnetic interference signal may be shielded outside the electromagnetic shielding layer 40, the controller cannot receive electromagnetic interference by the surrounding circuit, and the electromagnetic shielding layer 40 makes direct contact with the controller, so that heat generated in a working process of the controller may be transferred out.

It may be understood that the patch antenna and the pressure sensing circuit are only examples of the circuit unit 20, and the circuit unit 20 may be a circuit component with any function and a functional circuit composed of many same or different circuit components.

in order to realize this purpose, the embodiments of the present disclosure provide an electronic apparatus. The electronic apparatus includes the packaging structure 100 for a circuit unit 20. The electronic apparatus includes the packaging structure 100 for a circuit unit 20, and has at least the beneficial of the packaging structure 100 for a circuit unit 20, which is not described in detail herein.

What is described above is only a preferred embodiment of the present disclosure and does not limit the patent scope of the present disclosure The equivalent structure change made by using contents of the description and the drawings in the present disclosure and used directly/indirectly in other related technical fields under the concept of the present disclosure shall all fall within the scope of protection of the present disclosure.

1. A packaging structure for circuit units, comprising: a circuit baseplate, wherein the circuit baseplate is provided thereon with a plurality of circuit units comprising a silicon dioxide layer and an electronic device arranged on the silicon dioxide layer;
an insulator, wherein the insulator surrounds each of the plurality of circuit units; and
an electromagnetic shielding layer, wherein the electromagnetic shielding layer covers each of the plurality of circuit units and the insulator.

2. The packaging structure for circuit units according to claim 1, wherein the insulator is convexly arranged between each of the plurality of circuit units such that the insulator and the silicon dioxide layer form a recess in a surrounding mode, and the electromagnetic shielding layer fills the recess to contact with the silicon dioxide layer.

3. The packaging structure for circuit units according to claim 1, wherein the silicon dioxide layer is arranged on the circuit baseplate through a surface mounting.

4. The packaging structure for circuit units according to claim. 1, wherein the electromagnetic shielding layer is made of semiconductive silver adhesive, and the semiconductive silver adhesive is obtained by adding metal particles into an epoxy resin.

5. The packaging structure for a-circuit units according to claim 1, wherein the electromagnetic shielding layer is made of aluminum nitride ceramics.

6. The packaging structure for circuit units according to claim 1, wherein the electromagnetic shielding layer is made of organic glass.

7. The packaging structure for circuit units according to claim 1, wherein the electromagnetic shielding layer is provided with a through hole, the circuit unit is a patch antenna, and the patch antenna comprises:
a radio-frequency circuit, wherein the radio-frequency circuit is formed on the silicon dioxide layer;
a radiating body, wherein the radiating body is formed on a surface, facing away from the silicon dioxide layer, of the electromagnetic shielding layer; and
a feeder, wherein the feeder penetrates through the through hole and is connected to the radio-frequency circuit and the radiating body.

8. The packaging structure for circuit units according to claim. 1, wherein the circuit units comprise a photosensitive element, the photosensitive element being formed on the silicon dioxide layer, and the electromagnetic shielding layer being transparent or semitransparent.

9. The packaging structure fora-circuit units according to claim 1, wherein the electromagnetic shielding layer is provided with at least two through holes, the circuit units comprise a pressure sensing circuit, and the pressure sensing circuit comprises:
a controller, wherein the controller is formed on the silicon dioxide layer;
a pressure sensor, wherein the pressure sensor is arranged on a surface, facing away from the silicon dioxide layer, of the electromagnetic shielding layer; and
a connecting line, wherein the connecting line penetrates through the through hole and is connected to the controller and the pressure sensor.

10. An electronic apparatus, comprising the packaging structure for circuit units according to claim 1.
